(19) United States
(12) Patent Application Publication
(10) Pub. No.: US 2019/0164720 A1
(43) Pub. Date: May 30, 2019

(54) LIQUID SAMPLE CARRIER

(71) Applicant: National Cheng Kung University, Tainan City (TW)

(72) Inventors: Po-Tsung Hsieh, Kaohsiung City (TW); Chung-Jen Chung, Tainan City (TW); Shih-Wen Tseng, Tainan City (TW); Tzu-Ting Tsai, Tainan City (TW); Chih-Chien Lin, Tainan City (TW); Wen-Kuei Chuang, Tainan City (TW)

(21) Appl. No.: 15/827,164

(22) Filed: Nov. 30, 2017

(51) Int. Cl. H01J 37/20; B01L 3/00

(52) U.S. Cl. CPC H01J 37/20; B01L 3/508; H01J 37/26; B01L 2300/12; B01L 2300/0848; B01L 2300/0887

(57) ABSTRACT

A liquid sample carrier includes a first base that includes a first carrying portion having a first sample holding surface, and a second base that is connectable to the first base and that includes a second carrying portion, a support layer, and a second sample holding surface. The second carrying portion is stackable on the first carrying portion, and has a surrounding wall defining a through hole. The support layer is connected to the second carrying portion and has a window area corresponding to the through hole, and a peripheral area surrounding the window area. The second sample holding surface is connected to the support layer. A sample receiving area is formed between the first and second sample holding surfaces.

### FIELD

The disclosure relates to a liquid sample carrier, and more particularly to a liquid sample carrier having a sample receiving area formed between two sample holding surfaces of two bases.

### BACKGROUND

Electron microscopy is widely used in sample examination in the fields of biotechnology, semiconductor, nano-material, etc. Since electron microscopy is generally conducted in a vacuum environment, a test sample is required to be in an anhydrous and non-volatile form through pretreatments according to characteristics thereof. However, for many test samples, appearance and morphology of the anhydrous and non-volatile form are different from that of a liquid form, drying of the test sample is likely to tremendously change the appearance and morphology, and thereafter inaccurate examination results are obtained. Therefore, if the test sample is a liquid sample, a biological sample or a sample that requires in-situ observation in an aqueous environment, the test sample is generally packaged in a liquid sample carrier so as to be isolated from the vacuum environment.

Referring to FIGS. 1 and 2, a conventional liquid sample carrier 9 includes two bases 91 that are fitted to and connected to each other. Each of the bases 91 includes a film layer 911, and a copper ring 912 peripherally connected to the film layer 911. When a liquid sample 90 is to be packaged in the liquid sample carrier 9, the liquid sample 90 is first loaded on the film layer 911 of one of the bases 91, and an adhesive is applied between the bases 91 to bond the bases 91 together, such that the liquid sample 90 is packaged in the liquid sample carrier 9 and confined in a sample receiving area defined by the film layers 911 of the bases 91. Since the film layers 911 of the bases 91 are generally made from a flexible material, the sample receiving area defined thereby is expandable and may receive an excess amount of the liquid sample 90, and thus, the images of the liquid sample 90 obtained from the electron microscope may have poor resolution. Besides, the flexible film layers 911 are unable to provide sufficient support to the liquid sample 90, and thus the liquid sample 90 may move around in the liquid sample carrier 9 during the electron microscope examination.

### SUMMARY

Therefore, an object of the disclosure is to provide a liquid sample carrier that can alleviate at least one of the drawbacks of the prior art.

According to the disclosure, a liquid sample carrier includes a first base and a second base.

The first base includes a first carrying portion having a first sample holding surface.

The second base is connectable to the first base and includes a second carrying portion, a support layer, and a second sample holding surface.

The second carrying portion is stackable on the first carrying portion, and has a surrounding wall defining a through hole extending therethrough.

The support layer is connected to a surface of the second carrying portion and is directed toward the first carrying portion to strengthen the second carrying portion. The support layer has a window area corresponding in position to the through hole, and a peripheral area surrounding the window area and corresponding in position to the surrounding wall.

The second sample holding surface is connected to the support layer and faces the first sample holding surface.

A sample receiving area is formed between the first and second sample holding surfaces.

### BRIEF DESCRIPTION OF THE DRAWINGS

Other features and advantages of the disclosure will become apparent in the following detailed description of the embodiment with reference to the accompanying drawings, of which:

FIG. 1 is a schematic exploded view of a conventional liquid sample carrier;

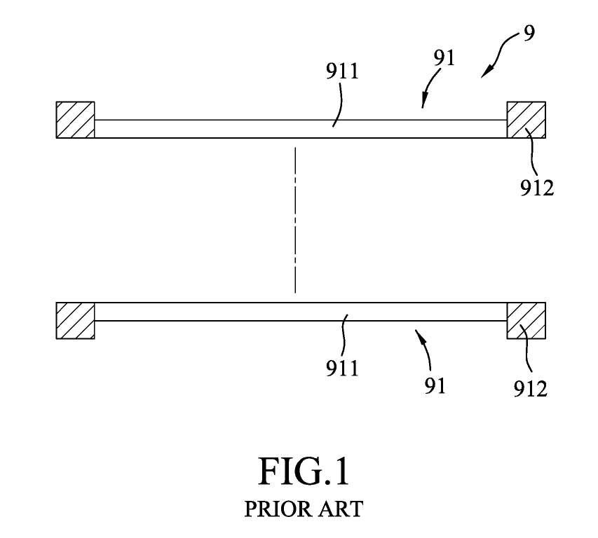

FIG. 2 is a schematic view illustrating consecutive steps of packaging a liquid sample in the conventional liquid sample carrier;

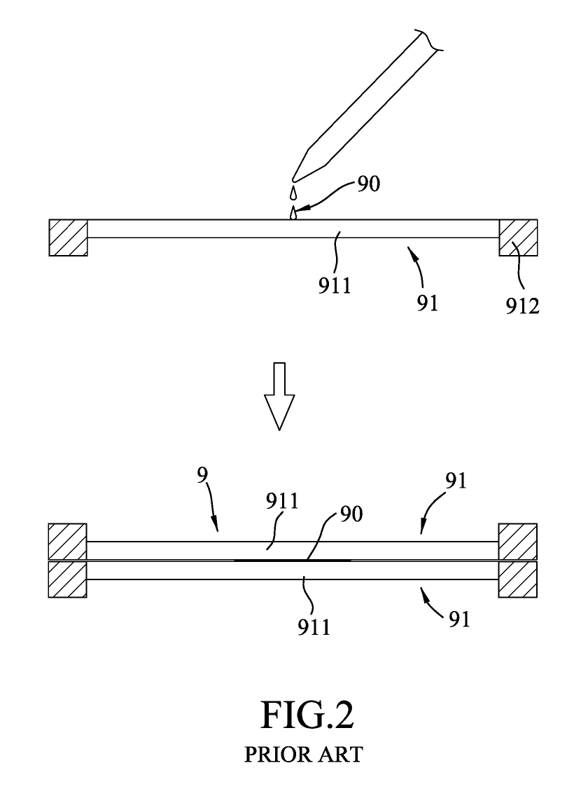

FIG. 3 is a schematic view of an embodiment of a liquid sample carrier according to the disclosure;

FIG. 4 is a schematic exploded view illustrating the embodiment of the liquid sample carrier;

FIG. 5 is a schematic top view illustrating a second base of the embodiment of the liquid sample carrier;

FIG. 6 is a schematic view illustrating consecutive steps of packaging a liquid sample in the embodiment of the liquid sample carrier; and

FIG. 7 is a schematic exploded view illustrating another configuration of the embodiment of the liquid sample carrier.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

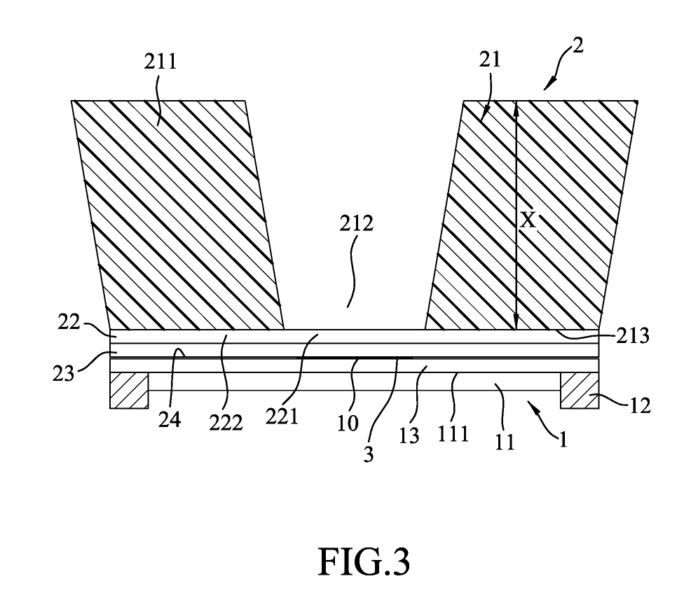

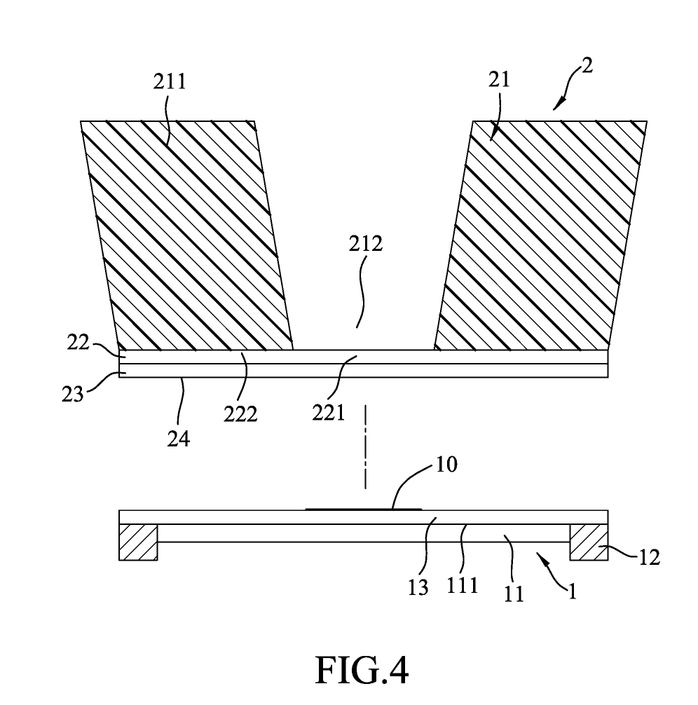

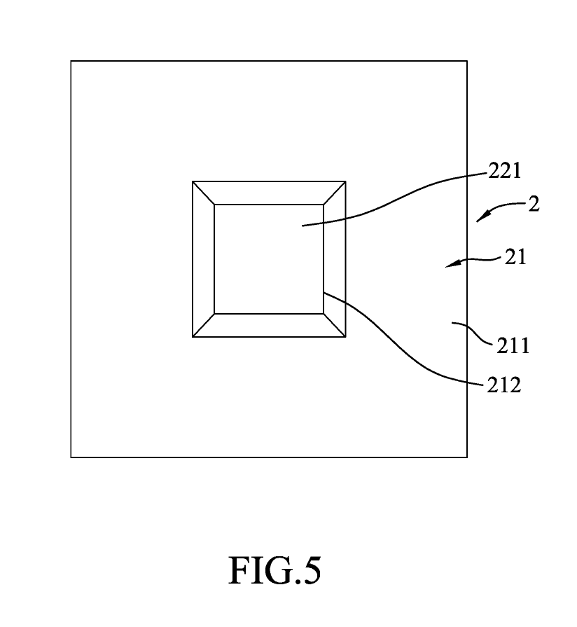

Referring to FIGS. 3 to 5, an embodiment of a liquid sample carrier is adapted for carrying a liquid sample 10, and includes a first base 1 and a second base 2.

The first base 1 includes a first carrying portion 11 that has a first sample holding surface 111 facing the second base 2. In this embodiment, the first base 1 further includes a frame portion 12 that is connected to a periphery of the first carrying portion 11, and a strengthening layer 13 disposed on the first carrying portion 11 and facing the second base 2. The first carrying portion 11 may include a carbon film made by the following steps: coating an organic film that is made of polyvinyl formal resins (Formvar, the registered trade name) on the frame portion 12; coating a carbon film on the organic film so that the organic film and the carbon film cooperatively define the first carrying portion 11; and cladding the strengthening layer 13 on the first carrying portion 11 so as to enhance structural strength of the first carrying portion 11. In this way, the strengthening layer 13 cooperates with the first carrying portion 11 to form a strength-improved laminate. The frame portion 12 is made from a material different from that of the first carrying portion 11. In the embodiment, the frame portion 12 may be made from copper and may be ring-shaped. In one form, the first base 1 may further include a rigid portion (not shown) that is connected between the first carrying portion 11 and the strengthening layer 13 and that may be grid-shaped, so that the structural strength of the first base 1 can be enhanced. The strengthening layer 13 may be made from an electroconductive material. The electroconductive material may be selected from the group consisting of silicon carbide (SiC), graphene, aluminum-doped zinc oxide (AZO), zinc oxide (ZnO), and any combinations thereof.

The second base 2 is connectable to the first base 1, for example with an adhesive, and includes a second carrying portion 21, a support layer 22, and a reinforcing layer 23. The second carrying portion 21 has a hardness greater than that of the first carrying portion 11, and may be a silicon substrate or an alumina substrate. The second carrying portion 21 is a block structure instead of a film for supporting loads. The second carrying portion 21 is stackable on the first carrying portion 11, and has a surrounding wall 211 that defines a through hole 212 extending therethrough. The surrounding wall 211 has a thickness (X) around 250 μm. The through hole 212 may have a circular or polygonal cross-sectional dimension.

The support layer 22 of the second base 2 is connected to a surface 213 of the second carrying portion 21 and is directed toward the first carrying portion 11 to strengthen the second carrying portion 21. The support layer 22 has a window area 221 that corresponds in position to the through hole 212, and a peripheral area 222 that surrounds the window area 221 and that corresponds in position to the surrounding wall 211. The second carrying portion 21 may be produced by using a microelectromechanical system, and in this way, the second carrying portion 21 and the support layer 22 are required to be immersed in an acidic solution or an alkaline solution for a few hours. Thus, the support layer 22 may be preferred to be made from acid-resistant or alkali-resistant materials. Furthermore, the support layer 22 has a relatively great hardness, so that the second carrying portion 21 with the support layer 22 has an improved structural strength for supporting the liquid sample 10. The support layer 22 may be made from an inorganic material. The inorganic material may be selected from silicon nitride (SiN), silica (SiO₂), alumina (Al₂O₃) and any combinations thereof.

The reinforcing layer 23 is formed on the support layer 22 and faces the first carrying portion 11. The reinforcing layer 23 may be made from an electroconductive material. The electroconductive material is selected from the group consisting of graphene, metals, a transparent conductive oxide, electroconductive ceramics and any combinations thereof. The graphene has relatively great conductivity and hardness. The conductive ceramics may be silicon carbide, molybdenum dioxide, or zirconia. Besides, based on the operation principle of the electron microscopy, the electroconductivity of the reinforcing layer 23 further enhances resolution of images obtained from the electron microscope examination, such as by using a transmission electron microscope (TEM). The second base 2 further includes a second sample holding surface 24 that is connected to the support layer 22 and faces the first sample holding surface 111. Specifically, the second sample holding surface 24 is formed on the reinforcing layer 23. A sample receiving area 3 is formed between the first and second sample holding surfaces 111, 24.

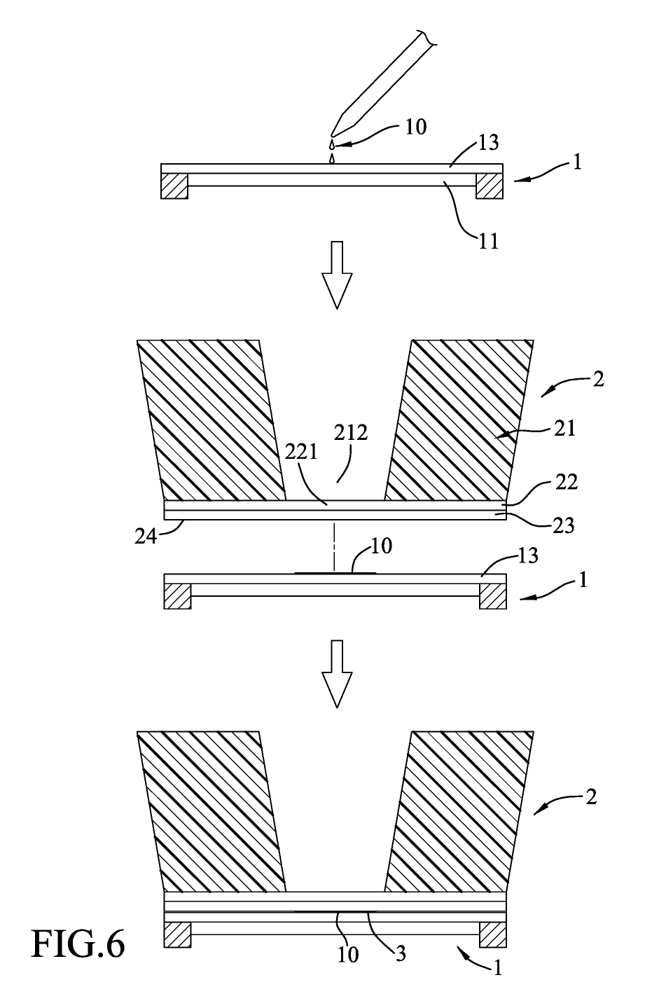

Referring to FIGS. 3 and 6, when a liquid sample 10 is to be packaged in the liquid sample carrier according to the disclosure, the liquid sample 10 is first loaded on the strengthening layer 13 of the first base 1, and the second base 2 is then covered on the first base 1. Since both the second carrying portion 21 and the reinforcing layer 23 have sufficient hardness, the liquid sample 10 in excess will be expelled from the sample receiving area 3 due to compression of the first and second bases 1, 2. Subsequently, an adhesive is applied between the strengthening layer 13 of the first base 1 and the reinforcing layer 23 of the second base 2 so as to connect the second base 2 to the first base 1. By this way, the liquid sample 10 is well packaged in the sample receiving area 3, corresponds in position to the window area 221 of the second support layer 22 of the second base 2, and is ready to be examined by the electron microscope (e.g., the TEM). During examination of the specimen, the specimen is first disposed on the electron microscope in a manner that the second base 2 is under the first base 1, and receives an electron beam emitted from the electron microscope. The electron beam emitted downwardly through the first base 1 partially transmits through the liquid sample 10 and partially scatters out upon hitting the liquid sample 10. The transmitted beam will further pass through the window area 221 of the support layer 22 and the through hole 212 of the second carrying portion 21. Finally, the transmitted beam exits the through hole 212 and the scattered beam will be magnified and focused by electromagnetic lenses so that an image of the liquid sample 10 for analysis is obtained.

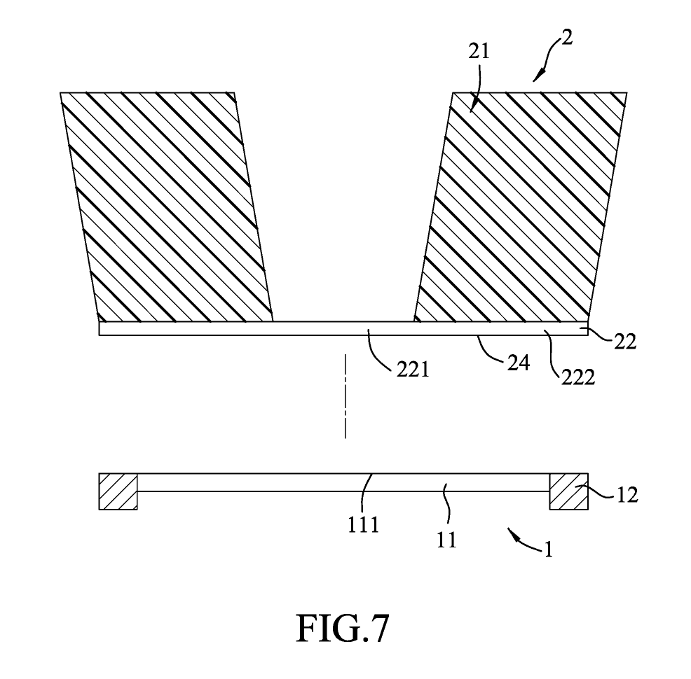

Referring to FIG. 7, in another configuration of the embodiment of the liquid sample carrier according to the disclosure, the strengthening layer 13 of the first base 1 and the reinforcing layer 23 of the second base 2 are dispensed. In this configuration, the second sample holding surface 24 is formed on the window area 221 and the peripheral area 222 of the support layer 22.

To sum up, by virtue of the hardness adjustment of the second carrying portion 21 and the first carrying portion 11, and use of the support layer 22 to enhance the structural strength of the liquid sample carrier, the liquid sample carrier of the disclosure has an improved bearing capacity and is capable of providing adequate support, and the liquid sample 10 can be stably confined in the sample receiving area 3 and is in an appropriate amount. Therefore, the problem of the conventional liquid sample carrier is alleviated, and resolution and quality of the image generated by the electron microscope can be improved. Besides, assembly and alignment of the first and second bases 1, 2 can be achieved in a simplified manner.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A liquid sample carrier, comprising:
a first base including a first carrying portion having a first sample holding surface; and
a second base connectable to said first base and including
a second carrying portion stackable on said first carrying portion, and having a surrounding wall defining a through hole extending therethrough,
a support layer connected to a surface of said second carrying portion and directed toward said first carrying portion to strengthen said second carrying portion, said support layer having a window area corresponding in position to said through hole, and a peripheral area surrounding said window area and corresponding in position to said surrounding wall, and
a second sample holding surface connected to said support layer and facing said first sample holding surface,
wherein a sample receiving area is formed between said first and second sample holding surfaces.

2. The liquid sample carrier of claim 1, wherein said second carrying portion has a hardness greater than that of said first carrying portion.

3. The liquid sample carrier of claim 1, wherein said second sample holding surface is formed on said window area and said peripheral area of said support layer.

4. The liquid sample carrier of claim 1, wherein said second base further includes a reinforcing layer formed on said support layer and facing said first carrying portion, said second sample holding surface being formed on said reinforcing layer.

5. The liquid sample carrier of claim 4, wherein said reinforcing layer is made from an electroconductive material selected from the group consisting of graphene, metals, electroconductive ceramics and any combinations thereof.

6. The liquid sample carrier of claim 1, wherein said support layer is made from an inorganic material.

7. The liquid sample carrier of claim 6, wherein said inorganic material is selected from silicon nitride (SiN), silica (SiO₂), alumina (Al₂O₃) and any combinations thereof.

8. The liquid sample carrier of claim 1, wherein said first carrying portion includes a carbon film.

9. The liquid sample carrier of claim 1, wherein said second carrying portion is one of a silicon substrate and an alumina substrate.

10. The liquid sample carrier of claim 1, wherein said first base further includes a frame portion connected to a periphery of said first carrying portion and being made from a material different from that of said first carrying portion.

11. The liquid sample carrier of claim 10, wherein said frame portion is made from copper.

12. The liquid sample carrier of claim 1, wherein said first base further includes a strengthening layer disposed on said first carrying portion and facing said second base.

13. The liquid sample carrier of claim 12, wherein said strengthening layer is made from an electroconductive material.

14. The liquid sample carrier of claim 13, wherein said electroconductive material is selected from the group consisting of silicon carbide (SiC), graphene, aluminum-doped zinc oxide (AZO), zinc oxide (ZnO), and any combinations thereof.
